(19) United States
(12) Patent Application Publication
(10) Pub. No.: US 2015/0037540 A1
(43) Pub. Date: Feb. 5, 2015

(54) TEMPLATE, A METHOD OF PROCESSING A TEMPLATE, A METHOD OF PRODUCING A PATTERN, AND RESIST

(71) Applicant: KABUSHIKI KAISHA TOSHIBA, Tokyo (JP)

(72) Inventors: Kei KOBAYASHI, Kanagawa-ken (JP); Seiji MORITA, Tokyo (JP)

(21) Appl. No.: 14/182,866

(22) Filed: Feb. 18, 2014

(30) Foreign Application Priority Data
Jul. 31, 2013 (JP) 2013-159244

(51) Int. Cl. G03F 7/00; H01L 21/027

(52) U.S. Cl. CPC G03F 7/0002; H01L 21/0274
USPC 428/172; 438/780; 438/778; 425/385; 427/133; 216/66

(57) ABSTRACT

An aspect of one embodiment, there is provided a template employed in imprinting including a substrate having a main surface, a pattern including a concave portion and a convex portion on the main surface, and a liquid-repellent layer selectively provided on the convex portion, the liquid-repellent layer having liquid-repellency to resist having fluidity in the imprinting.

### CROSS REFERENCE TO RELATED APPLICATION

This application is based upon and claims the benefit of priority from prior Japanese Patent Application No. 2013-159244, filed on Jul. 31, 2013, the entire contents of which are incorporated herein by reference.

### FIELD

Exemplary embodiments described herein generally relate to a template employed in imprinting, a method of processing the template, a method of producing a pattern and resist employed in imprinting.

### BACKGROUND

Recently, a method of producing a pattern employing imprint technique has been focused. Photo imprint technique is one of most promising imprinting techniques for applying semiconductor lithography. A method of producing a pattern employing photo imprint technique is described below.

Photo-curing resin with a liquid state is coated on a surface of a substrate. Next, a pattern surface of a template is contacted to a photo-curing resin to fill the photo-curing resin into a concave portion of the pattern surface by capillary phenomenon.

The photo-curing resin is hardened by photo irradiation. Subsequently, the template is released from the photo-curing resin hardened as the resin pattern. The substrate is etched by using the resin pattern as a mask to produce a pattern.

When the pattern surface of the template is contacted to the photo-curing resin, a thin portion of the photo-curing resin is present between the pattern surface of the template and the convex portion of the substrate. The thin photo-curing resin is remained as a residual film on the substrate after the releasing of the template.

The residual film influences on etching accuracy of the substrate. Accordingly, the substrate is essentially etched after the residual film is removed.

### BRIEF DESCRIPTION OF THE DRAWINGS

FIG. 1A is a cross-sectional view showing a template according to an embodiment;

FIGS. 1B, 1C are cross-sectional views showing a method of processing the template according to the embodiment;

FIGS. 2A, 2B are cross-sectional views showing a method of processing the template according to the embodiment;

FIG. 2C is a cross-sectional view showing the method of processing the template according to the first embodiment;

FIGS. 3A-3C are cross-sectional views showing the method of processing the template according to the first embodiment;

FIGS. 4A-4C are cross-sectional views showing the method of processing the template according to the first embodiment;

FIGS. 5A-5C are cross-sectional views showing a method of processing a template according to a second embodiment;

FIGS. 6A-6C are cross-sectional views showing the method of processing the template according to the second embodiment;

FIG. 7 is a chemical formula showing a base agent in a photo-curing resin according to the embodiment;

FIG. 8 is a chemical formula showing a dilute agent in the photo-curing resin according to the embodiment;

FIG. 9 is a chemical formula showing an etching resistance agent in the photo-curing resin according to the embodiment.

### DETAILED DESCRIPTION

An aspect of one embodiment, there is provided a template employed in imprinting including a substrate having a main surface, a pattern including a concave portion and a convex portion on the main surface, and a liquid-repellent layer selectively provided on the convex portion, the liquid-repellent layer having liquid-repellency to resist having fluidity in the imprinting.

Another aspect of one embodiment, there is provided a method of processing a template employed in imprinting, the template including a substrate having a main surface and a pattern comprising a concave portion and a convex portion on the main surface, the method including providing an embedded layer on the main surface including the concave portion and the convex portion of the pattern to embed the embedded layer into the concave portion, thinning the embedded layer to expose the convex portion, providing a liquid-repellent layer on the embedded layer in the concave portion and on the exposed convex portion, the liquid-repellent layer having liquid-repellency to resist, the resist having fluidity in the imprinting, and removing the embedded layer and the liquid-repellent layer on the embedded layer to leave the liquid-repellent layer on the exposed the convex portion.

Another aspect of one embodiment, there is provided a method of producing a pattern including coating a resist on a substrate, the resist having fluidity in imprinting, contacting a template employed in the imprinting to the resist, the template including a substrate having a main surface and a pattern including a concave portion and a convex portion on the main surface, a liquid-repellent layer with liquid-repellency to the resist being selectively provided on the convex portion, the resist being embedded in the concave portion, hardening the resist in a state of the template being contacted to the resist, and releasing the template from the hardened resist.

Another aspect of one embodiment, there is provided a method of producing a pattern including, coating a resist on a substrate, the resist having fluidity in imprinting, contacting a template employed in imprinting to the resist in an atmosphere including condensate gas, the template including a substrate having a main surface and a pattern including a concave portion and a convex portion on the main surface, the resist being embedded into the concave portion, both the condensate gas between the concave portion and the resist and the condensate gas between the convex portion and the resist being agglomerated to produce liquid, hardening the resist in a state of the template being contacted to the resist, and releasing the hardened resist from the template.

Another aspect of one embodiment, there is provided a resist employed in imprinting including a base agent hardened by ultraviolet irradiation, a dilute agent to dilute the base agent; and an etching resistance agent having resistance to etching of a substrate, wherein each of the base agent, the dilute agent and the etching resistance agent includes one of hydroxyl group and carbonyl group and the etching resistance agent includes acrylate with a circular structure.

Embodiments will be described below in detail with reference to the attached drawings mentioned above. Throughout the attached drawings, similar or same reference numerals show similar, equivalent or same components, and the description is not repeated.

### First Embodiment

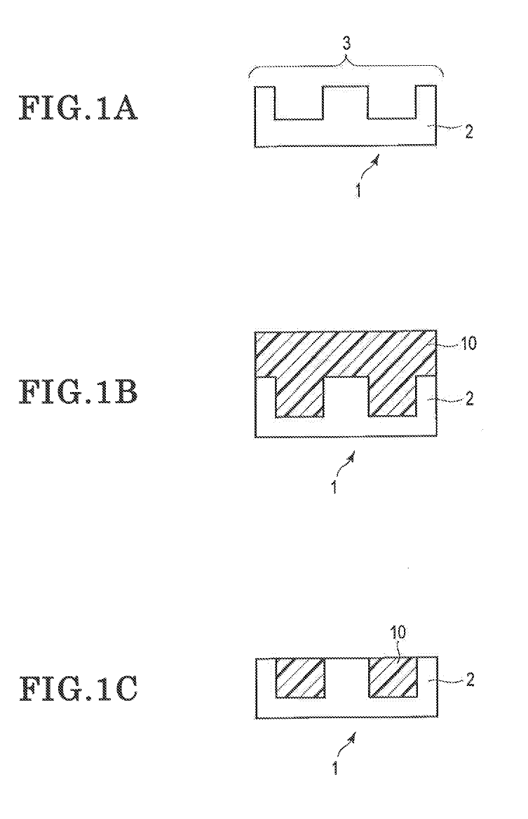

FIG. 1A is a cross-sectional view showing a template which is applied to a method of processing a template 1 according to an embodiment. The template 1, which is employed in a photo imprinting method, is described in the embodiment.

The template 1 includes a transparent substrate 2 as a body and a pattern 3 having a concave portion and a convex portion on a main surface of the transparent substrate 2. The main surface is the opposed another surface to a prescribed surface received light irradiation. The pattern 3 includes a pattern corresponding to a device pattern to be provided on a wafer. The pattern 3 is provided by etching the transparent substrate 2. Hereinafter, the concave portion and the convex portion of the pattern 3 are called a pattern concave portion and a pattern convex portion, respectively. A material of the transparent substrate 2 is composed of quartz, for example.

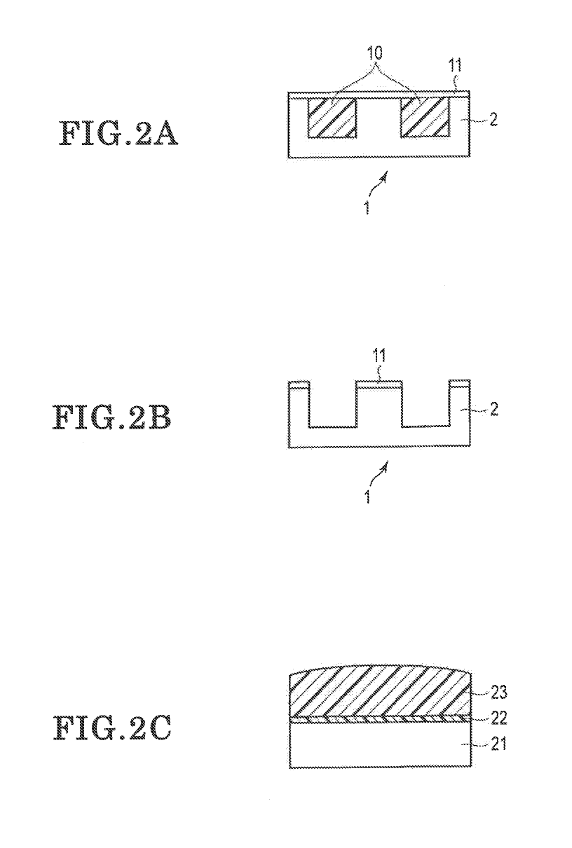

FIGS. 1B-2B are cross-sectional views showing a method of processing the template according to the embodiment.

As shown in FIG. 1B, a resist (embedded layer) is embedded into the pattern concave portion to be provided on the main surface of the template 1. The resist 10 is generally composed of organic polymer. Water or organic solvent soluble in water or organic polymer is used as the organic polymer. Such the organic polymer is polyvinyl alcohol or polystyrene, for example.

As shown in FIG. 1C, the resist 10 is etched back to expose the pattern convex portion. On the other hand, the resist 10 is still embedded in the pattern concave portion. The resist 10 is etched back by a process of Reactive Ion Etching (RIE) using oxygen gas.

As shown in FIG. 2A, a liquid-repellent layer 11 is provided on the pattern convex portion and the resist 10. The liquid-repellent layer 11 has liquid-repellency against a photo-curing resin with a liquid state, in other words, has lower affinity with the photo-curing resin with a liquid state. The liquid-repellent layer 11 can be provided by Chemical Vapor Deposition (CVD), Chemical Vapor Surface Modification (CVSM) or liquid immersion technique. In such a manner, it is capable to provide the liquid-repellent layer 11 having a thickness of a few nm as a molecular layer.

Flolinate oligomer such as fluoroalkyl silane oligomer or the like, flolinate polymer such as fluoroalkyl polymer, fluoroethr polymer or the like can be employed as a material of the liquid-repellent layer 11. Specifically, OPTOOL DSX (Daikin Industries), Fluorosyl FSD 4500 (Cytonix), FLUOROLINK S10 (Solvay Solexis), Aquaphobe CF (Gelest Corporation), tridecafluoro-1,1,2,2-tetrahydrooctyltrimethoxysilane, tridecafluoro-1,1,2,2-tetrahydrooctyltrichlorosilane, heptadecafluoro-1,1,2,2-tetrahydrodecyl trichlorosilane are utilized, for example.

The liquid-repellent layer 11 using the materials described above has a contact angle not less than seventy degrees to the photo-curing resin with a liquid state.

Bonding between the resist 10 and the liquid-repellent layer 11 is generally weaker than that of between the pattern convex portion (quartz) and the liquid-repellent layer 11. As a result, the liquid-repellent layer 11 is processed by water or organic solvent to selectively remove the liquid-repellent layer 11 on the resist 10. Furthermore, the resist layer in the pattern concave portion can be also selectively removed by well-known technique. In such a manner, the template 1 including the liquid-repellent layer 11 selectively provided on the pattern convex portion, can be obtained. The liquid-repellent layer 11 has liquid-repellency to the photo-curing resin with a liquid state which is hardened by ultraviolet. Accordingly, template 1 according to the embodiment substantially has liquid-repellency only on the pattern convex portion to the photo-curing resin with the liquid state.

FIGS. 2C-4C are cross-sectional views showing the method of processing the template according to the first embodiment.

As shown in FIG. 2C, an adherence film 22 employed in imprinting is provided on a substrate 21. A coating solution is coated on the adherence film 22 by rotational coating, for example. The coating solution is heated to produce the adherence film 22. Next, a photo-curing resin with a liquid state is provided on the adherence film 22. The photo-curing resin 23 is posed radical polymerization by photo irradiation to be employed as a resist in nano-imprint technology, for example.

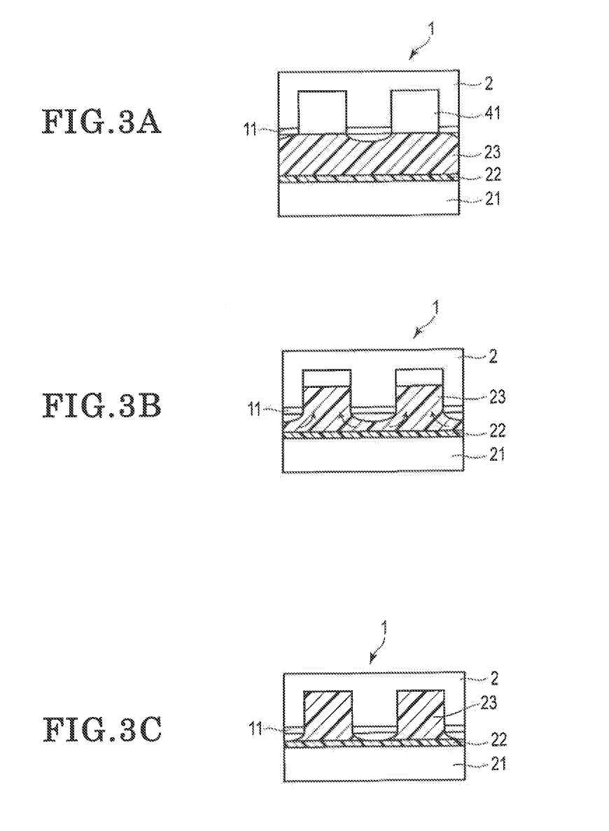

As shown in FIG. 3A, the template 1 is contacted to the photo-curing resin with the liquid state 23. Further, the template 1 is approached the substrate 21 as shown in FIG. 3B so that the photo-curing resin with the liquid state 23 is filled into the pattern concave portion by capillary phenomenon as shown in FIG. 3C. In the situation described above, the photo-curing resin with the liquid state 23 in a gap between the liquid-repellent layer 11 and the substrate 21 transfers on the substrate 21 to flow into the pattern concave portion by the liquid-repellent layer 11, as shown in FIG. 3B by using an arrow. As a result, a thickness of the photo-curing resin 23 in the gap is sufficiently lowered, a thickness uniformity of a residual film is sufficiently lowered with the thickness of the photo-curing resin 23 in the gap being sufficiently lowered, or the photo-curing resin 23 in the gap being scarcely present. In other words, generation of the residual film is suppressed in the first embodiment.

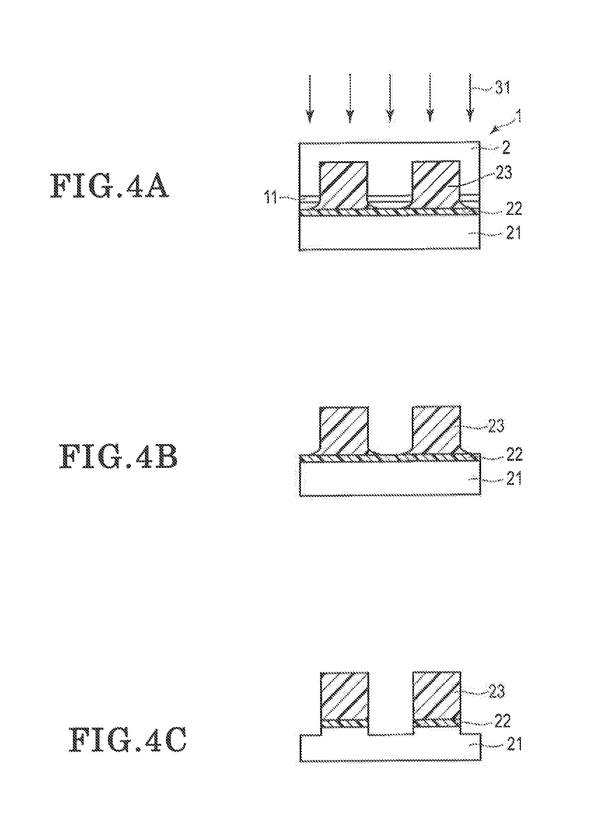

As shown in FIG. 4A, the photo-curing resin 23 is irradiated with light 31 through the template 1 to harden the photo-curing resin 23. Subsequently, the template 1 is released from the hardened photo-curing resin 23 (resin pattern), as shown in FIG. 4B.

As described above, generation of the residual film is suppressed. Accordingly, processing steps to remove the residual film can be omitted to realize a nano-imprint process having higher throughput. Further, the residual film is sufficiently thin to be easily removed even when the residual film is removed.

The thickness of the residual film is measured by Spectrafx 200 (KLA-Tencor Corporation) in the first embodiment. The thickness of the residual film is conformed to be not thicker than 5 nm, which is below the measurement limit.

As shown in FIG. 4C, the substrate 21 is etched using the resin pattern 23 as a mask to produce the pattern.

Here, a fine electrode pattern, a fine wiring pattern or the like is provided when an underlying film of the resin pattern 23 (the uppermost layer of the substrate 21) is a ploy-crystalline silicon film, a metal film or the like. On the other hand, a fine contact hole pattern, a fine gate insulator or the like is provided when the underlying film of the resin pattern 23 (the uppermost layer of the substrate 21) is an insulator. Further, a fine element isolation trench (STI) is provided when the underlying film of the resin pattern is a semiconductor substrate.

Furthermore, generation of the residual film can be suppressed to effectively protect from influence of the residual film on the etching of the substrate in the first embodiment. Therefore, a fine pattern having a half pitch being not larger than 20 nm, for example, 15 nm can be precisely provided.

The method of producing the pattern using the template described above can be repeatedly utilized to obtain a fine pattern in a semiconductor device with high performance.

### Second Embodiment

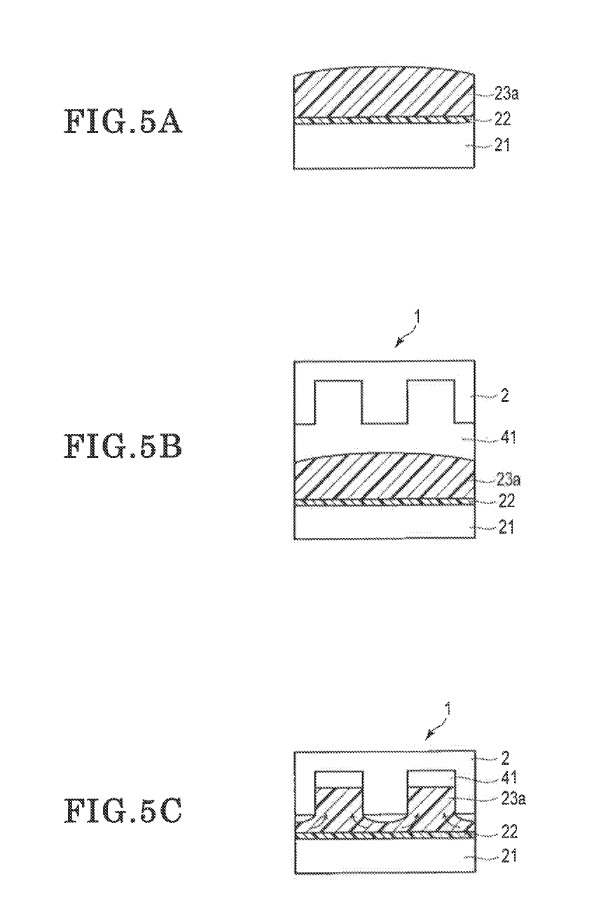

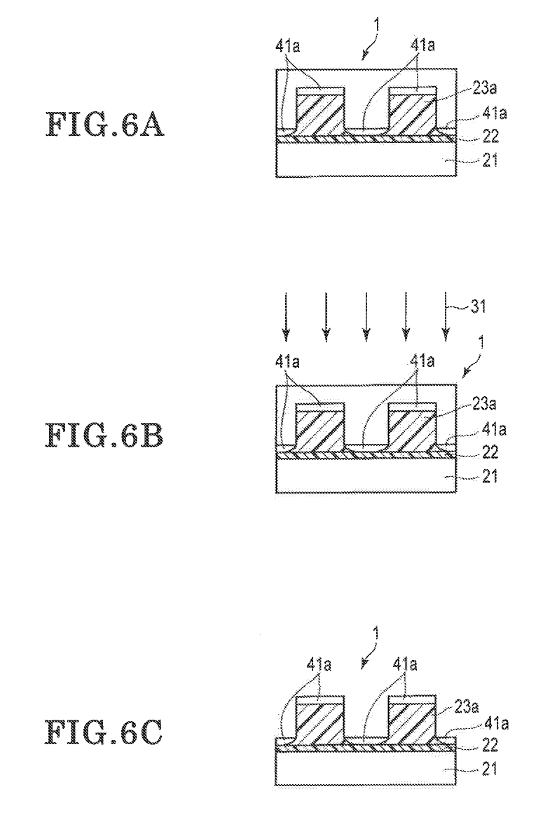

FIGS. 5A-6C are cross-sectional views showing a method of processing a template according to a second embodiment. Throughout the attached drawings, similar or same reference numerals show similar, equivalent or same components, and the description is not repeated.

First, as the same as the first embodiment, an adherence film 22 employed in imprinting is provided on a substrate 21, as shown in FIG. 5A. Subsequently, a photo-curing resin with a liquid state 23a is provided on the adherence film 22. The photo-curing resin 23a is composed of a condensate gas 41 which is not easily dissolved, namely, not to easily absorb, as described after. The photo-curing resin 23a has an absorption ratio of condensate gas in room temperature being not more than 20%. A monomer component constituting the photo-curing resin 23a is 2-Hydroxyethyl Acrylate, 4-Hydroxybutyl Acrylate, 2-Hydroxy-3-phenoxypropyl acrylate, Glycerol 1,3-diglycerolate diacrylate, 1,4-Phenylene diacrylate or the like.

Next, an atmosphere in a holder (not shown) installed the substrate 21 the photo-curing resin 23a or the like is filled with the condensate gas 41, as shown in FIG. 5A. Subsequently, a template 1 is provided at an upper side of the photo-curing resin 23a. The condensate gas 41 is liquidized under a condition in higher pressure to some extent than room temperature. The condensate gas 41 is composed of pentafluoropropane (PFP), for example.

The template 1 is contacted to the photo-curing resin 23a to be approached the substrate 21 as shown in FIG. 5C so that the photo-curing resin with a liquid state 23a is immersed in the pattern concave portion.

The template is approached the substrate 21 so that pressure is applied to the condensate gas 41 to be liquidized. Accordingly, the condensate gas 41 is change to be a condensate solution (liquid). The photo-curing resin with the liquid state 23a in a gap between the between pattern convex portion and the substrate 21 is pressed by the condensate liquid 41a on the pattern convex portion so that the photo-curing resin with a liquid state 23a is transferred on the substrate into the pattern concave portion. As a result, a thickness of the photo-curing resin 23a in the gap is decreased to be sufficiently thinned or the photo-curing resin 23 in the gap is scarcely present.

Viscosity of the photo-curing resin 23a can be lower to easily flow the liquidized photo-curing resin 23a into the pattern concave portion. Viscosity of the photo-curing resin 23a in room temperature, 20° C.±15° C., for example, is a value not more than 10 CP. The photo-curing resin 23a can have not affinity to the condensate gas, and further, has non-affinity to the liquidized condensate gas (liquid) to easily flow the liquidized photo-curing resin 23a into the pattern concave portion.

As shown in FIG. 6B, the photo-curing resin 23a is irradiated with light 31 through the template 1 to harden the photo-curing resin 23a. Subsequently, the template 1 is released from the hardened photo-curing resin 23a (resin pattern), as shown in FIG. 6C.

A condensate liquid 41a remained on the substrate 21 or the template 1 is selectively removed by cleaning or etching, for example. Subsequently, the substrate 21 is etched to produce the pattern as the same as the first embodiment.

The thickness of the residual film is measured by Spectrafx 200 (KLA-Tencor Corporation) in the second embodiment. The thickness of the residual film is conformed to be not more than 5 nm, which is below the measurement limit.

Furthermore, the condensate gas 41 absorbed by the photo-curing resin with a liquid state 23a (resist) is conformed to be not more than 20%. A detailed description is explained below.

A resist employed in imprinting with a weight of 20 g is installed in a flask with a volume of 50 cc. The resist is conducted hardening reaction by radical polymerization. The resist is bubbled by PFP gas using a PFP gas nozzle for 300 seconds under a flow rate of 1.0 l/min.

An agglomeration gas absorption amount is defined as ΔM where a weight of an initial resist is M0 introduced from formula (1) described below and a weight of a resist after being bubbled in a period of 300 seconds using PFP gas is M300.

ΔM [%]=(M0/M300)×100 (Formula 1)

The agglomeration gas absorption amount of the photo-curing resin (resist) 23a according to the method described above is confirmed to be not more than 20% in the second embodiment.

The photo-curing resin (resist) 23a is further described below.

The photo-curing resin 23a includes a base agent (resist material), a dilute agent (resist material) and an etching resistance agent (resist material). The base agent is hardened by ultraviolet irradiation. The dilute agent dilutes the base agent. The etching resistance agent has etching resistance to the etching of the substrate. Each of the base agent, the dilute agent and the etching resistance agent includes hydroxyl group and carbonyl group, and the etching resistance agent further includes acrylate with a circular structure.

(1) On Base Agent

As the base agent, multifunctional acrylate is employed to bridge between molecules to harden a photo-curing resin by using ultraviolet irradiation.

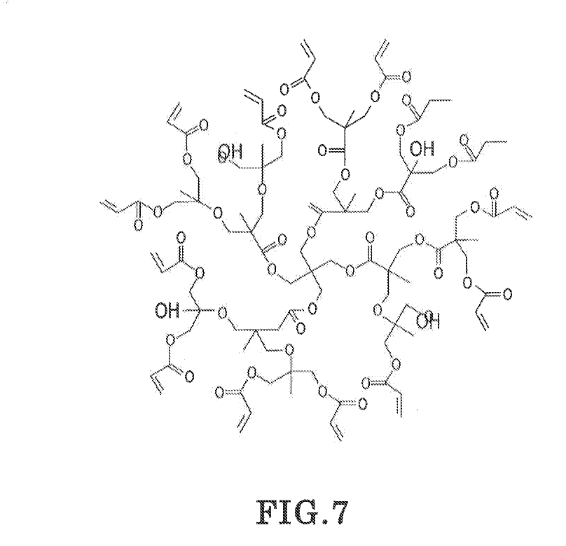

In the base agent, agglomeration energy density or solubility (square root of agglomeration energy density) is necessary to be enlarged not to be liquidized by a condensate gas liquid such as a PFP gas, for example. Therefore, at least one selected from hydroxy group (—OH) and carbonyl group (C═O) is more included in the base agent. FIG. 7 is a chemical formula showing the base agent of the photo-curing resin including hydroxy group.

Specifically, monomers including a tree like structure such as dendritic acrylate (fourteen functional groups, twelve functional groups, octafunctional groups) or the like can be used as the base agent. Acrylate monomers with not less than hexafunctional groups can obtain a sufficient hardened film. Especially, in a case that the base agent including dendritic acrylate with a functional groups between fourteen functional groups—octafunctional groups, etching resistance to the substrate to be patterned in imprinting can be improved to be able to enlarge a selective ratio in etching.

The following materials can be also utilized as the base material, such as tripentaerythritolacrylate (octafunctional groups), dipentaerythritolhexaacrylate (hexafunctional groups), pentaerythritoltetraacrylate (tetrafunctional groups), pentaerythritoltriacrylate (trifunctional groups), glycerol 1,3-glycerolatediacrylate (bifunctional groups), 1,4-phenylenefenilendiacrylate (bifunctional groups).

(2) On Dilute Agent

In the dilute agent, monofunctional acrylate, monofunctional vinyl ether, bifunctional vinyl ether, or the like are used to decrease viscosity of the resist.

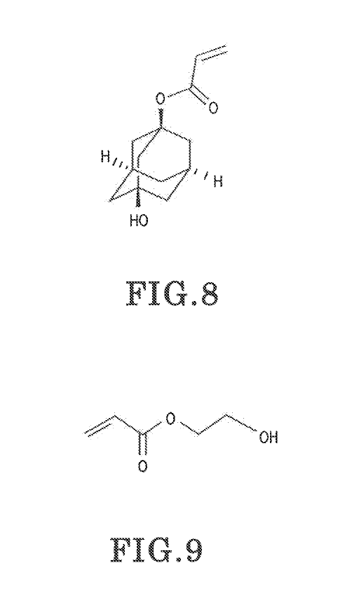

In the dilute agent, agglomeration energy density or solubility (square root of agglomeration energy density) is necessary to be enlarged not to be liquidized by condensate gas liquid such as PFP gas, for example. Therefore, at least one selected from hydroxy group (—OH) and carbonyl group (C═O) is more included in the base agent. FIG. 8 is a chemical formula showing a dilute agent including hydroxy group.

Specifically, hydroxyalkylacrylate with low viscosity such as hydroxyethylacrylate (monofunctional group) or the like can be used as the dilute agent.

The following materials can be also utilize as the dilute material, such as hydroxypropylacrylate, 6-carboxyethylacrylate, methylacrylate, methylmethacrylate, hydroxybutylacrylate, hydroxyethylmetamethacrylate, hydroxyphenoxypropylacrylate, 2,3-dihydroxypropylacrylate, or the like.

Furthermore, low viscosity vinylether monomer, such as ethyleneglycolmonovinylether or the like can be used as the dilute agent.

(3) On Etching Resistance Agent

In the etching resistance agent, acrylate having a circular structure can be used to retain etching resistance of the resist.

In the etching resistance agent, agglomeration energy density or solubility (square root of agglomeration energy density) is necessary to be enlarged not to be liquidized by condensate gas liquid such as PFP gas, for example. Therefore, at least one selected from hydroxy group (—OH) and carbonyl group (C═O) is more included in the base agent. FIG. 9 is a chemical formula showing an etching resistance agent including hydroxy group.

Specifically, monomers having an alicyclic structure such as hydroxyadamantylacrylate (monofunctional group) or the like can be used as the etching resistance agent.

The following materials can also utilize as the dilute material, such as hydroxyadamantydiacrylate, hydroxyisobornyacrylate, hydroxyphenoxypropylacrylate, hydroxydimethyloltricyclodecanediacrylate, hydroxyfluorenediacrylate or the like can be used as the etching resistance agent.

A photo polymerization initiator employed in radical polymerization can be used as the polymerization initiator of the photo-curing resin 23a in the second embodiment.

Specifically, IRGACURE369, IRGACURE184, DAROCURE1173 can be used as the polymerization initiator.

A photo polymerization initiator employed in hybrid polymerization can be used in a case of using monomers with vinyl ether series. The photo polymerization initiator can be used both radical polymerization using onium salt, or the like, and cationic polymerization.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template employed in imprinting, the template comprising:
a substrate having a main surface;
a pattern including a concave portion and a convex portion on the main surface; and
a liquid-repellent layer selectively provided on the convex portion, the liquid-repellent layer having liquid-repellency to resist having fluidity in the imprinting.

2. The template of claim 1, wherein
a material of the liquid-repellent layer contains a fluorine-containing polymer.

3. The template of claim 2, wherein
the fluorine-containing polymer composed of one of fluoroalkyl silane oligomer, fluoroalkyl polymer and fluoroethr polymer.

4. The template of claim 1, wherein
a contact angle of the liquid-repellent layer to the resist is not less than seventy degrees.

5. A method of processing a template employed in imprinting, the template comprising a substrate having a main surface and a pattern comprising a concave portion and a convex portion on the main surface, the method comprising:
providing an embedded layer on the main surface including the concave portion and the convex portion of the pattern to embed the embedded layer into the concave portion;
thinning the embedded layer to expose the convex portion;
providing a liquid-repellent layer on the embedded layer in the concave portion and on the exposed convex portion, the liquid-repellent layer having liquid-repellency to resist, the resist having fluidity in the imprinting, and
removing the embedded layer and the liquid-repellent layer on the embedded layer to leave the liquid-repellent layer on the exposed the convex portion.

6. The method of claim 5, wherein
A material of the liquid-repellent layer contains a fluorine-containing polymer.

7. The method of claim 6, wherein
the fluorine-containing polymer is one of fluoroalkyl silane oligomer, fluoroalkyl polymer and fluoroethr polymer.

8. The method of claim 5, wherein
A wet process is included in the removing of the embedded layer and the liquid-repellent layer on the embedded layer to leave the liquid-repellent layer on the exposed the convex portion.

9. The method of claim 8, wherein
the wet process is conducted by using a solution including water or organic agent.

10. The method of claim 5, wherein
the embedded layer includes one of polyvinyl alcohol and polystyrene.

11. The method of claim 5, wherein
An RIE process is included in the thinning of the embedded layer to expose the convex portion of the pattern.

12. A method of producing a pattern, comprising:
coating a resist on a substrate, the resist having fluidity in imprinting;
contacting a template employed in the imprinting to the resist, the template including a substrate having a main surface and a pattern including a concave portion and a convex portion on the main surface, a liquid-repellent layer with liquid-repellency to the resist being selectively provided on the convex portion, the resist being embedded in the concave portion;
hardening the resist in a state of the template being contacted to the resist; and
releasing the template from the hardened resist.

13. The method of claim 12, wherein
a material of the liquid-repellent layer contains a fluorine-containing polymer.

14. The method of claim 13, wherein
the fluorine-containing polymer is one of fluoroalkyl silane oligomer, fluoroalkyl polymer and fluoroethr polymer.

15. The method of claim 12, wherein
a contact angle of the liquid-repellent layer to the resist is not less than seventy degrees.

16. A method of providing a pattern, comprising:
coating a resist on a substrate, the resist having fluidity in imprinting;
contacting a template employed in imprinting to the resist in an atmosphere including condensate gas, the template including a substrate having a main surface and a pattern including a concave portion and a convex portion on the main surface, the resist being embedded into the concave portion, both the condensate gas between the concave portion and the resist and the condensate gas between the convex portion and the resist being agglomerated to produce liquid;
hardening the resist in a state of the template being contacted to the resist, and
releasing the hardened resist from the template.

17. The method of claim 16, wherein
the resist has non-affinity to the condensate gas.

18. A resist employed in imprinting, the resist being coated on a substrate including a pattern provided by imprinting, the resist comprising:
a base agent hardened by ultraviolet irradiation;
a dilute agent to dilute the base agent; and
an etching resistance agent having resistance to etching of a substrate;
wherein each of the base agent, the dilute agent and the etching resistance agent includes one of hydroxyl group and carbonyl group and the etching resistance agent includes acrylate with a circular structure.

19. The resist of claim 18, further comprising:
a photo polymerization initiator employed in radical polymerization.
